(19) United States
(12) Patent Application Publication
(10) Pub. No.: US 2013/0025673 A1
(43) Pub. Date: Jan. 31, 2013

(54) SOLAR CELLS AND METHOD FOR PRODUCING SAME

(71) Applicants: Egon Huebel, Feucht (DE); Andre Richter, Thun (CH)

(72) Inventors: Egon Huebel, Feucht (DE); Andre Richter, Thun (CH)

(73) Assignee: SOMONT GMBH, Umkirch (DE)

(21) Appl. No.: 13/638,491

(22) PCT Filed: Apr. 1, 2011
(86) PCT No.: PCT/EP2011/001652

§ 371 Date: Sep. 28, 2012

(30) Foreign Application Priority Data
Apr. 1, 2010 (DE) 10 2010 014 554.8
Apr. 1, 2010 (DE) 10 2010 014 555.6

(51) Int. Cl. H01L 31/0224; H01L 31/18; C25D 17/00

(52) U.S. Cl. 136/256; 204/242; 438/66; 257/E31.124

(57) ABSTRACT

Solar cells, where at least one conductor is mechanically and electrically connected to the solar cell and/or further conductors by conductive cladding. The conductive cladding is preferably deposited electrolytically or galvanically from solution or is produced by plasma-spraying. In addition, methods for connecting solar cells by means of at least one conductor and/or for connecting conductors on solar cells, wherein at least one electrically-conductive conductor is mechanically and electrically connected by depositing conductive cladding from solution onto the solar cell and/or at least one conductor. Also, a device for depositing a mechanically-connecting and electrically-conductive cladding from solution onto solar cells in electrolytic cells, comprising means for receiving at least one conductor, preferably a collector or bus-bar conductor contacting surface to be deposited in the electrolyte of the electrolytic cell, preferably at least partially providing electrical contact with a seed-layer of the solar cell, and preferably simultaneously supporting the solar cell.

The present invention relates to solar cells in which at least one conductor is mechanically and electrically conductively connected to the solar cell and/or further conductors by means of conductive cladding, wherein the conductive cladding is preferably deposited electrolytically or galvanically from a solution or is produced by plasma spraying. The invention further relates to a method for connecting solar cells by means of at least one conductor and/or for connecting conductors on solar cells, wherein at least one electrically conductive conductor is mechanically and electrically connected by depositing a conductive cladding from solution onto the solar cell and/or onto at least one further conductor. The invention further relates to a device for depositing a mechanically connecting and electrically conductive cladding from solution onto solar cells in electrolytic cells, comprising means for receiving at least one conductor, preferably a collector or busbar conductor contacting the surface to be deposited in the electrolyte of the electrolytic cell, preferably at least partially providing preferably electrical contact with a seed layer of the solar cell, and preferably simultaneously supporting the solar cell.

Solar cells made of semiconductor materials, especially silicone, are produced in several steps. In most cases, the side of the solar cell facing the sun, also known as front side, is provided with electrically conductive current collectors which usually consist of an electrically conductive grid structure, the so-called front contacts. Alternatively, there are also versions where the contacts are located on the back. Usually, a large number of metallic conductors with a very small cross-sectional area, referred to below as contact fingers, run parallel across the contact side of the solar cell. These contact fingers cross, electrically connecting and usually at right angles, so-called collectors, especially busbars, i.e. collectors with a long contact surface area to conduct the electricity supplied by many contact fingers and generated by the solar cell to the consumer. Because the short circuit current of a solar cell, e.g. a solar cell that has the usual dimensions of 156×156 mm² can be more than 12 amperes, the cross-sectional area of the busbars is significantly greater compared to the contact fingers. This is achieved by means of a wide and thereby shading design usually measuring 2 mm in width. For this purpose, electrical conductors in the form of e.g. small metallic tapes are typically soldered onto the busbar(s) upon completion of the solar cell, providing an extensive contact surface area. In combination with the many contact fingers, this results in a significant area of shading on the solar cell which reduces its efficiency. For a standard solar cell, shading due to front contacts amounts to about 7% of the geometric surface area. Various attempts are therefore made to reduce this percentage of shading. For example, DE 10 2008 030 262 A1 describes a solar cell that is first produced with contact fingers and short collecting connectors only, i.e. without any busbars providing a contact surface area, and that the short collecting connectors are then electrically conductively connected to an external connector device by means of connecting wires of different lengths and thicknesses. In the process, the connector device is connected to the contact fingers or to the short collecting connectors according to a specific pattern such that it results in minimal shading.

The electrically conductive connecting of the connecting wires to the contact fingers or the collecting or busbar connectors is an additional step after completion of the solar cell, i.e. usually after metalizing the contact fingers. The sensitive solar cell, however, can basically break at any step of the process. This also applies to soldering or wire-bonding the connecting wires, the collectors, the busbars and the contact fingers to the wafer or to the solar cell. Apart from soldering, essentially two methods for producing the contacts, i.e. the contact fingers and the busbars or the short collectors, are known. Printing the wafer with an electrically conductive paste followed by baking, also referred to as firing, is a widely used method. The disadvantages of this method, however, lie in the cost of the conductive paste in the screen printing method as well as the limits to obtaining narrow contact fingers that are as high as possible. Narrow contact fingers reduce shading. Therefore, efforts focus more and more on producing a plated grid structure by electroplating. The structured and electrically conductive thin seed layer required for this process can be produced more precisely. Compared to paste printing, electroplating allows narrower contact fingers and thereby slightly less shading. In addition, the electrochemical method is less expensive than the printing and baking of electrically conductive pastes of greater layer thickness, and it does not subject the material to high temperature strains. DE 10 2005 039 100 A1 discloses an electroplating device for metalizing the grid structure of fragile solar cells. To do so, a framework is used that can hold several solar cells and transport them through a continuous flow system. The framework is equipped with gaskets such that the back sides of the solar cells are not moistened with electrolytes. Contacts are arranged on protrusions that conduct the electroplating current directly to the surface to be metalized. Since the contacts as well as the material for electroplating are metalized in the electrolyte, they must be cleaned or stripped clear at intervals.

DE 10 2007 020 449 A1 teaches how to metalize fragile solar cells in a so-called “cup plater” in which the material to be electroplated is placed on several layers at the upper opening of the cup which simultaneously form the electrical contacts for introducing the electroplating current to the grid structure consisting of contact fingers and collectors (busbars and short, connected collectors). Because these cathodic contacts are located in the electrolyte, they must be de-metalized as needed.

DE 10 2005 038 450 A1 relates to another process for producing contacts for solar cells in a continuous flow system. Here, electric contacting takes place outside of the electrolyte at the dry back side of the solar cell, which is not to be electroplated and which is the upper side in this case. The side of the solar cell facing the sun undergoes high intensity illumination during the electroplating process in order to render it low-resistance for the electroplating current. DE 10 2007 022 877 A1 shows mesh-like conductor wire systems for connecting individual solar cells where electricity from emitter and base electrodes in solar cells that are arranged next to one another is alternately conducted away either via direct electrode contact or via busbar conductor contacts.

The purpose of the present invention is to make available improved solar cells as well as methods and devices for their manufacture. The purpose of the present invention is especially to provide solar cells with conductors that conduct electricity, especially contact fingers, collectors, especially busbars and solar cell connective conductors which ensure that the shaded area will be smaller than it conventionally is at present. In addition, solar cells are to be produced more easily, more cost-effectively and more robustly when the manufacturing method according to the invention as well as the device designed for this purpose according to the invention are used.

These problems can be solved by means of a solar cell where at least one conductor is mechanically and electrically conductively connected to the solar cell and/or further conductors by means of conductive cladding.

The conductive cladding which connects the conductor and the solar cell or conductors on the solar cell mechanically and electrically conductively with each other is preferably the result of an electrolytic, i.e. galvanic (current-carrying) or electrochemical (currentless) deposition from solution or is created by plasma-spraying the conductor.

In the plasma spraying process, also referred to as plasma cladding, direct current voltage is usually applied to create an arc between an anode and a cathode and the gas or gas mixture flowing through the plasma torch is passed through the arc, becoming ionized in the process. Ionization creates a superheated (up to 20,000 K), electrically conductive gas consisting of positive ions and electrons. Powder (standard particle size distribution: 5-120 μm; with certain devices, particle sizes down to 100 nm are possible) is introduced into this plasma jet where it is melted due to the high plasma temperature. The plasma jet grabs the powdered particles, hurling them on the workpiece to be coated, in this case the solar cell and the conductor. The gas molecules return to a stable state already within a very short period of time; therefore, the plasma temperature drops already after a short distance. Plasma cladding is performed in ambient air, in an inert atmosphere (under a protective gas such as argon), in vacuum or even underwater. Speed, temperature and the composition of the plasma gas are important factors in the quality of the layer.

The benefit of producing solar cells according to the invention is that methods are used that connect the solar cell and conductor, or conductor and conductor, without significantly heating one of the two components and without exerting significant forces on the components to be connected, and furthermore the fact that directly conductive structures are deposited as cladding in the process. Therefore, the strain put on cells and conductors is less than with conventional joining techniques such as soldering or gluing, resulting in less breakage. It also avoids the problem of differences in thermal expansion coefficients between solar cell and conductor (e.g. copper, silver) which lead to mechanical strains when the solder cools and hardens. Furthermore, in contrast to gluing, the release of solvent, the limited current-carrying capacity of the glue, and the mechanical stresses and strains arising when the glue is applied and hardened are avoided when the advantageous method of deposited cladding is applied.

Other known methods merely place conductive structures in position and create a conductive connection by applying a steady pressure. The problem with this method is in ensuring that steady pressure is applied for years, and the potential formation of oxides between the conductor and the solar cell, particularly because solar cells expand in sunlight and then shrink again.

The invention is explained below for the most part by referring to galvanic and electrochemical, preferably galvanically produced mechanical and electrically conductive cladding. Although these are the preferred embodiments, they can for the most part be transferred to plasma spray claddings as well.

The mechanical and electrically conductive connection between the conductor and the solar cell, or between the conductors, is formed when conductor/solar cell and/or conductor/conductor and/or solar cell/solar cell are in contact while the cladding is deposited, or are arranged at such a small distance from each other that the conductive deposit, in other words, the conductive cladding, are mechanically and electrically conductively connected during the electrolytic or plasma deposition process. This connection by means of mutual deposition cladding occurs precisely where the conductor and the solar cell or the two conductors are electrically conductive and in contact with each other or, alternatively, closely spaced. The method is therefore particularly suitable for connections between materials with small or large surface areas. On the one hand, the surfaces of the components can be partially insulated to avoid a mechanical connection and a conductive cladding; on the other hand it is possible to design a precisely conductive surface on non-conductive materials such as silicon wafers with a conductive seed layer. Another advantage of a connection created by conductive cladding is that the conductive cladding is uniform with respect to its composition, thickness and dimensioning, whereby its conductive properties as well as its mechanical strength turn out uniform and controllable.

It is advantageous to use light- or laser-induced electroplating in the manufacture of solar cells according to the invention. In the process, deposition in the intended area is controlled by a local increase in temperature and/or by light-induced chemical excitation. This allows all or part of seed layers and also insulation pressures to be replaced. For example, the laser can be moved along the area to be electroplated (conductor/solar cell), thereby activating the deposition very precisely.

The term conductor when used in the context of solar cells in general covers any form of electrically conductive connection that conducts the electricity produced by the solar cell to the consumer. Conventional conductors are wires and printed or soldered conducting paths, or conducting paths that have been extensively electroplated onto the solar cell. In one preferred embodiment, the solar cell according to the invention concerns solar cells where the conductor is selected from the group consisting of contact fingers, collectors, preferably busbars, more preferably busbar conductors (explained below in more detail) and solar cell connective conductors. These conductors, such as contact fingers, can tap the electricity at the solar cell [and] conduct it directly or preferably via collectors or busbars/busbar conductors to consumers while the connective conductors electrically connect individual solar cells with each other. In a particularly preferred embodiment, the conductors such as contact fingers, collectors, preferably busbars, more preferably busbar conductors and/or solar cell connective conductors, preferably all these connective conductors, are designed as conductor wires. This, however, is not necessary. If for example the solar cell already has collectors/busbars contacting its surface and/or contact fingers such as printed or possibly burnt-in electrically conductive pastes or electroplated conducting tracks, even these conductors contacting its surface area can be connected with other conductors, especially wire conductors, by means of electrolytic deposition or plasma spraying of conductive claddings as well. For example, any conducting tracks whose surface area is in contact with the solar cell can be connected by means of wire conductors by the deposition of conductive claddings (vertical connection, one above the other) or even by applying an electrically conductive seed layer to the solar cell between two wire conductors that share a contact surface area (horizontal connection, adjacent) electrolytically or by plasma spraying. In other words, in the solar cell according to the invention, solar cell and conductor, or conductor and conductor, or even horizontally adjacent conductors, can be mechanically and electrically conductively connected in such a way by placing one on top of the other (vertical) and by depositing/spraying on the conductive cladding. The vertical connection, i.e. solar cell and conductor(s) and/or conductors among themselves are located one on top of the other, by means of conductive cladding is particularly preferred. Here, one must distinguish between the established galvanic manufacture of contact fingers or collectors and busbars with a contact surface area, and the connection of two existing components such as conductor/solar cell or conductor/conductor according to the invention by means of a common electrolytically deposited or plasma-sprayed cladding according to the invention.

The solar cell according to the invention is suitable for any geometrical shape, size and technology of solar cells, especially for crystalline and thin-layer solar cells, preferably those based on semiconductor materials such as silicone and gallium arsenide. Solar cells can be produced according to the invention on an organic basis as well.

In one preferred embodiment, the present invention in the most general sense also relates to a solar cell, preferably made of semiconductor material, especially preferably based on silicone or gallium arsenide, with contacts on the front and/or back to conduct the electricity generated away by means of many contact fingers and with at least one busbar, wherein at least one of the busbars is implemented as a busbar conductor whose conductor is mechanically and electrically conductively connected to the contact fingers. The busbar conductor is different from the deposition cladding described above, preferably a conductive solid object such as a metal wire or a (preferably flexible) circuit board with a conductor usually made of metal (especially suited for back contact cells) wherein the conductor forms the busbar conductor together with the deposited conductive cladding as a whole and wherein furthermore the cladding ensures the desired mechanical and electrically conductive contact to the solar cells and/or other conductors. In conventional galvanically produced busbars, the busbar itself is the galvanically deposited mass (a conductive component); a busbar conductor consists of at least two components: a pure conductor, e.g. metal wire, and a contact material such as for example electroplated cladding, electrochemical cladding, plasma spray cladding or solder. In a preferred embodiment, the front contacts, i.e. the contact fingers and/or the busbar conductor, are arranged on the side facing the sun. The busbar conductor according to the invention is a busbar version without a contact surface area which, in contrast to the common solder paste and electroplated busbar designs, is preferably formed as a wire-shaped conductor, thus a wire-shaped busbar conductor.

The novel busbar conductors consist of a non-insulated electrical conductor. This conductor is preferably electrically conductively connected to the start layer or the seed layer of the grid structure of the solar cell. Preferably, this connection is implemented by means of the advantageous galvanic, electrochemical or plasma spray deposition method already described above. Alternatively, there is also the possibility of embedding these busbar conductor solar cells in the electrically conductive paste applied via a printing process followed by baking or firing in the conventional technique. Electroplating the conductors e.g. to the electrically conductive seed layer of the solar cell, however, is technically easier to implement and more cost-effective.

In another preferred embodiment, the invention therefore relates to a solar cell with a busbar conductor where at least one busbar conductor is mechanically and electrically conductively connected to the solar cell by means of electroplated cladding and where the busbar conductor is preferably wire-shaped.

In another preferred embodiment, the invention relates to a solar cell as referred to above where at least one busbar seed layer, which is electrically conductively connected to a contact finger seed layer, has a mechanical (preferably firm) and an electrically conductive connection to at least one busbar conductor, where this connection between the busbar seed layer and the busbar was preferably made by (i) electroplating or (ii) embedding and baking into a conductive paste.

In a particularly preferred embodiment, the conductive cladding of the solar cell according to the invention is selected from claddings that were produced electrolytically, i.e. electrochemically or galvanically from solution or by plasma spraying. Preferably, the conductive cladding for the solar cells according to the invention consists of conductive metals or metal alloys, preferably metals and metal alloys based on copper, silver, nickel and/or tin, conductive hydrocarbons and/or carbons, for example nanotubes and fullerenes.

The conductive cladding used according to the invention can preferably consist of one or more cladding layers made of the same or different materials, preferably different conductive materials. For example, a nickel layer or another conductive cladding that is compatible with the base material can be deposited first in order to prevent direct contact between the solar cell and copper, and only then copper cladding or conductive cladding made of a less expensive material that establishes the desired large-scale connection to the solar cell components can be deposited in order to make a good connection to the conductor, e.g. copper wire. Next, another cladding layer consisting of silver, tin or another material can be deposited to prevent copper oxidation. Preferably, each layer is applied using separate devices.

One embodiment of the solar cell with conductor according to the invention, preferably a collector or a busbar conductor, the length of which extends beyond the surface area of the solar cell at least on one side, has the additional advantage that the protruding free conductor end remaining on the solar cell can later be used to electrically interconnect the individual solar cells to produce standard solar cell arrangements/modules. The soldering on of metallic bands which is required in accordance with the state of the art is not required for these electrical connections, thereby reducing costs and avoiding the risk of breakage for individual solar cells, as is the case where connecting ribbons have to be soldered on. In one preferred embodiment, at least one conductor, preferably a collector, more preferably a busbar conductor, will preferably protrude beyond the surface area on at least one side of the solar cell as a conductor projection to provide an electric connection for the solar cell.

If the conductors, as described above, are produced e.g. by punching, etching or cutting, there are various design possibilities for the conductor projections, especially with regard to the subsequent electrical connections in the solar modules.

The preferably wire-shaped conductor of the busbar according to the invention is freely selectable with respect to its shape and cross section. The cross-sectional shape of the busbar conductor can preferably be round, oval or polygonal, preferably with a conductor cross section (preferably depending on the surface area of the solar cell and the material of the conductor) between 0.0002 mm² and 10 mm², preferably 0.001 mm² to 1 mm², more preferably with a conductor cross section of 0.02 mm² to 10 mm², preferably 0.1 mm² to 1 mm², where the busbar conductor is preferably flexible and malleable. The busbar conductor can be bigger and thus have lower resistance than the standard printed and/or electroplated busbars. Nonetheless, there will be less shading by comparison. A round copper wire with a diameter of e.g. 0.4 mm has significantly less line resistance than e.g. a 2 mm wide busbar consisting of silver conductive paste which furthermore is even more expensive than copper wire.

In one preferred embodiment, the conductor in the solar cell according to the invention, preferably a collector or busbar conductor, is electroplated onto the contact fingers through a (naturally reliable) electrical contact of the conductor, preferably a busbar conductor to many, preferably all, contact fingers without a busbar seed layer, or embedded in the conductive paste.

The seed layer is usually a thin, electrically conductive layer on the solar cell which preferably consists of an electrically conductive paste print or of sprayed-on, electrically conductive particles, conductive ink or a conductive (e.g. an area of the TCO [transparent conductive oxide] layer), or a nucleating area on the solar cell. Non-conductive seed layers with seed-forming function made of palladium, titanium, titanium/tungsten, etc. for example are also suitable for activating the surface layer of solar cells and conductors prior to deposition. Nucleation causes the conductive cladding to be preferentially deposited in the areas activated in this manner, thereby creating conductive seed layers completely cladding the nucleation seed layer where conductors/solar cells/other solar cell components can be electrically connected by means of the deposition of conductive claddings.

To achieve a high level of efficiency for the solar cell according to the invention as well as a complete solar module consisting of such solar cells, one or several of the conductors of the solar cell(s), preferably the collector, more preferably the busbar conductor, can be designed as a thin, electrically conductive tube. A fluid or gaseous cooling medium can be conveyed through this tubule which provides cooling for the electric conductor(s), preferably the collector(s), more preferably the busbar conductor(s) and the entire area surrounding a solar cell or a solar module. In one preferred embodiment therefore, at least one of the conductors, preferably a collector, more preferably a busbar conductor of the solar cell according to the invention is tubular so a cooling medium can be piped through it to increase the efficiency of electric conduction.

In its simplest embodiment, the conductor is a bright drawn wire, e.g. made of or based on copper or silver. A copper core with the copper diffusion barrier layer consisting for example of nickel or tin is advantageous. For lower conductivity requirements, iron-nickel alloys can be used as well. The conductor can also be wavy, as described, so as to equalize the mechanical tension between the silicone and the metal when differences in temperature are greater. The conductor can be produced by other means as well, e.g. by punching, shape-etching and cutting from the appropriate semi-finished products such as e.g. sheet metals. This allows particularly versatile shapes to be produced with respect to equalizing differences in temperature. For elongated conductors with a larger cross-sectional area, alloys whose thermal expansion coefficient is adapted to that of silicone or to the semiconductor material are suitable as well. One example is the material available under the trade name of Kovar. Its electrical conductance, however, is considerably less than that of e.g. copper. In one particularly preferred embodiment, at least one of the conductors of the solar cell, especially the collector or the busbar conductor of a solar cell according to the invention, is elongated or has a serpentine, triangular or sinusoidal shape, where it is preferentially formed by a wire or a punched, etched or cut part.

It is also advantageous if the solidity of the material that the conductor is made of is reduced by means of soft annealing so that the conductor is better able to adapt to the thermomechanical strains of the solar cell.

In one preferred embodiment, the solar cell according to the invention preferably consists of semiconductor material or thin-layer material, more preferably based on silicone or gallium arsenide or other semiconductors, where the thermal expansion coefficient of the conductor, preferably a collector or a busbar conductor, is adapted to the thermal expansion coefficient of the solar cell wafer e.g. by the use of an alloy or by physical processing.

Compared to the known completely electroplated front contacts which consist of silver, the electrolytic deposition time, in particular the electroplating time can be reduced considerably for the solar cell according to the invention because the conductor, preferably the collector or busbar conductor, must be electroplated to, for example, the seed layer on the solar cell using a thin layer only. Conventional electroplated busbars have layer thicknesses of 20 μm or more. For the invention, however, busbar conductors with a layer thickness of e.g. 5 μm are sufficient. The layer thickness at the thin contact fingers is greater than the 5 μm used in the busbar area, e.g. 10 μm, because this is where the field lines concentrate and the current density is higher.

The busbar conductor according to the invention has another very major advantage if its length extends beyond the surface area of the solar cell at least on one side. This at least one free conductor end per busbar can, while remaining on the solar cell, later be used to build an electric relay by interconnecting the individual solar cells into customary solar modules. In contrast to prior art, metallic bands do not need to be soldered on at all to make these electrical connections. Not only does this reduce costs but it also eliminates the risk of breakage of individual solar cells, as is the case where connecting ribbons have to be soldered on. If the conductors, as described above, are produced by punching, etching or cutting, there are various design possibilities for the conductor projections, especially with regard to the subsequent electrical connections in the solar modules. Moreover, several cells can be interconnected in the same electroplating process in order to produce a solar cell arrangement according to the invention as efficiently and cost-effectively as possible. For example, solar cell arrangements according to the invention, such as those shown in DE 10 2007 022 877 A1, can be produced by means of elastic, mesh-like conductor wire systems (as solar cell connective conductors) to connect individual solar cells, either directly or through collector contacts or busbar conductor contacts. In one particularly preferred embodiment of the solar cells according to the invention, the solar cell connective conductors extend over at least 50%, preferably 60%, more preferably 70%, most preferably 80% of one dimension, i.e. the length or the width of a solar cell, preferably in the direction of the current flow.

Another advantage in producing a conductive cladding by electroplating is that the contacts with the power source which are used for electroplating are themselves not electroplated and therefore do not need to be cleaned or even replaced at regular intervals.

In another aspect, the present invention relates to a method for connecting solar cells by means of at least one conductor and/or for connecting conductors on solar cells with one another, where at least one electrically conductive conductor is connected mechanically and electrically by depositing a conductive cladding from solution onto the solar cell and/or onto at least one further conductor. Preferably, the conductive cladding is selected from cladding produced electrolytically, galvanically or by plasma spraying. It is further preferred that the conductive cladding is selected from conductive metals or metal alloys, preferably metals and metal alloys based on copper, silver, nickel and/or tin, aluminum, conductive carbohydrates and/or carbons. Also, the conductive cladding preferably consists of one or several layers of cladding, preferably made of different conductive materials.

In one preferred embodiment, the conductor is selected from the group consisting of contact fingers, collectors, busbar conductors and solar cell connective conductors.

In an especially preferred embodiment, the invention relates to a method for electroplating solar cells in electrolytic cells where at least one electrically conductive conductor, preferably a collector or busbar conductor, is at least partially in electrical contact with the surface of the solar cell to be electroplated for supplying the electroplating current such that this conductor is permanently connected mechanically and electrically to the solar cell by electroplating.

For the method according to the invention, in particular the method described directly above, in a preferred embodiment, at least one conductor, preferably a collector or a busbar conductor, at pickups or carriers that extend beyond the length of the solar cell, will support the solar cell in the electrolytic cell during the electroplating process and preferably position and preferably transport it at a height such that only the underside of the solar cell to be electroplated is located in the electrolyte.

To form a contact between the conductor and the solar cell during the method according to the invention, in particular during the method described directly above, at least one of the conductors, preferably a collector or a busbar conductor, is pressed or drawn against the solar cells, preferably against the seed layer of the solar cell to be electroplated by means of placing it against one side of the solar cell and by applying force, preferably weight force, applied pressure, ram pressure exerted by a fluid, or spring force or magnets on the other side of the solar cells, or by fluid suction.

In a preferred embodiment for the method according to the invention, the electroplating current is fed into the conductor, preferably a collector or a busbar conductor that protrudes above the electrolyte level, on at least one conductor protrusion outside of the electrolyte in the version where electroplating is used.

The methods according to the invention are implemented particularly efficiently and therefore preferably in continuous flow systems, immersion bath systems or cup platers such that the conductors electroplated onto the solar cell or deposited electrochemically or deposited by means of plasma spraying, preferably collectors or busbar conductors, remain on the solar cell and can be utilized to further process the finished solar cell without any subsequent de-metalization.

In a preferred embodiment, the method according to the invention is used for connecting conductors such as contact fingers, collectors and/or busbar conductors with the solar cell or to interconnect them.

The method is particularly suitable for the production of solar cells, preferably the solar cells according to the invention referred to above. It is emphasized, however, that the cladding deposition method according to the invention is basically suitable for connecting any form of electric conductor, especially in the form of wires and connecting paths, mechanically and electrically conductive by means of a conductive cladding with a material that is electrically conductive or was rendered electrically conductive as a substrate.

In another preferred embodiment, the present invention relates to solar cells according to the invention and methods for producing same where the solar cells are implemented or manufactured without collectors or busbar conductors. Particularly preferred is that (i) the wires to be connected by means of a conductive cladding are located on the contact fingers and/or (ii) are transverse to the contact fingers.

An additional preferred embodiment focuses on solar cells according to the invention and methods for producing same where the solar cells are implemented or manufactured without collectors or busbar conductors and also without contact fingers and where the wires to be connected by means of a conductive cladding are located on active deposition areas of the solar cell, for example on seed layers or nucleation layers.

An additional preferred embodiment focuses on solar cells according to the invention and methods for producing same where the solar cells are preferably implemented or manufactured without collectors or busbar conductors and also without contact fingers and where the electricity is conducted away via many small wires that are connected to the solar cell and/or interconnected with each other by conductive cladding. This allows the total cross-sectional area of the conductor to be spread over many wires, thereby minimizing ohmic losses. In special embodiments of the solar cell, busbars and fingers can be left out completely, which reduces shading and distributes the transmission of electricity homogenously across the surface area.

The deposition active areas in the electroplating, electrochemical and plasma spraying method can be part of a solar cell or even an entire side of the cell. The deposition active area can also comprise both polarities of the solar cell on one side, especially for solar cells where both polarities are located on one side and where one wire in each case serves one polarity but where both polarities are reinforced at the same time when the conductive cladding is deposited.

Methods according to the invention for depositing the conductive cladding are preferred as well, especially by electroplating, where first one of the polarities is deposited or electroplated on, then equipped with new wires, and then the second polarity is deposited or electroplated on. In an alternative embodiment, the wires of the solar cell according to the invention cannot be continuously conductive: in the same way as a circuit board with wiring, as an insulated core, that is rendered partially (e.g. through metalization) conductive.

The method according to the invention can not only be used for the mechanically and electrically conductive connection of solar cells and conductors among each other but also for the mechanically and electrically conductive connection of solar cells and/or conductors with special elements such as for example components with bypass, protective and/or connective functions that are not solar-active. As further embodiments, even solar cells can be connected directly on other solar cells by means of the conductive cladding according to the invention if they can be brought into such spatial proximity that a conductive connection can be formed by depositing the cladding.

In a third aspect, the present invention is focused on a device for electroplating solar cells in electrolytic cells, comprising means for receiving at least one conductor, preferably a collector or busbar conductor, which is at least partially in contact, preferably providing electrical contact, with the solar cell in the electrolyte of the electrolytic cell at the surface to be electroplated, preferably a seed layer, and preferably simultaneously supports the solar cell, where the conductor projections preferably extend beyond the electrolyte level to connect the electroplating rectifier.

Preferably, such devices include pickups as a means for exerting a tension force at least on the area of the conduct which is located in the electrolyte of the electrolytic cell.

In a preferred embodiment, the device according to the invention also includes means that exert an attractive or a pressing force between the conductor and the solar cell with or without backing layers, preferably as applied pressure, weight force, magnetic force, elastic force or suction.

It is further preferable that the device according to the invention includes means for positioning the solar cell in a processing container such that the electrolyte level reaches no further than only to the underside of the solar cell.

The method according to the invention is suitable for the electrolytic and plasma spray treatment of solar cells on the side of the solar cell exposed to the sun or the front side, the back side or even both sides. To achieve this, the side(s) to be treated will need to be in contact with the electrolyte or with the plasma.

The following embodiments relate by way of example, but not restrictively, to the method according to the invention by means of electroplating.

In the methods according to the invention, especially where a cup plater is used, the untreated sides, which point upwards, will preferably stay dry. Thus, the back sides of solar cells, which are electrolyte-sensitive, are protected against damage. The electric contact takes place in the electrolyte directly on the structured surface which is usually furnished with an electrically conductive seed layer. In the process, the cathodic contact agents, which are located within the electrolytic cell in the electrolyte, are metalized galvanically as well. This metalization is used according to the invention, whereby the de-metalization process, which is customary otherwise, can be omitted completely. The contact agent according to the invention consists of at least one preferably wire-shaped, non-insulated electric conductor. The solar cells to be electroplated are brought into contact with the at least one extended (preferably elongated) conductor when the electroplating facility is being filled. In the process, they are positioned such that the path of the provided conductor(s), preferably collectors or busbars, of the solar cell is congruent with that of the wire-shaped contact agent(s). The solar cell thus rests on top of the preferably two extended (elongated) conductors. These conductors are located by an electrically insulated carrier or pickup which positions the height of the solar cells lying on top of the conductors such that only the conductors and the side of the solar cell to be treated, preferably the front side of the solar cell, is located below the electrolyte level. In a continuous flow system, the carrier or pickup can also be used to transport the solar cell through the continuous flow system. In a cup plater, the carrier preferentially is an integral component of this cup. The ends of the conductor, which preferably extend beyond the edges of the solar cell, are deflected upwards at the carrier or pickup; as a result, they protrude beyond the level of the electrolyte as conductor projections. Therefore, they remain dry and cannot be plated in this area. The same applies to the electrical connections that create a conductive conduit from the rectifier(s) to these conductor projections which protrude beyond the electrolytes. They are not coated with a metal layer. Even in a cup plater, the ends of the conductor remain dry. The conductors along the collectors or busbars arranged on the solar cells are electroplated onto the preferably existing seed layer according to the invention. Thus, they are mechanically solidly and electrically conductively connected with each other. In combination with the preferably protruding ends of the conductor(s), they form an enduring unit. Thus, the contact agents do not need to be de-metalized. The protruding ends of the conductor(s) or the conductor projections can advantageously be used later on for the electric interconnection of solar cells in solar modules. The soldering on of connective or amplifying conductors, which had previously been necessary to that end, is completely unnecessary in the method according to the invention.

Because the fragile solar cells, which in the electroplating system according to the invention are located on the conductors, are galvanically attached to these conductors, they can be transported through a continuous flow system very safely and gently, i.e. free from breakage. The direct electrical contacting of the surface to be electroplated on the grid structure also does not require the illumination used in the well-known LIP method (light-induced electroplating) by means of intensive light sources in the electrolyte in order to make the solar cells low-resistance for the electroplating current. This saves a considerable amount of energy in the production of solar cells according to the invention.

The cross-section of the collectors and busbars, preferably busbar conductors, can be adapted to the conductive requirements. Even if the cross-section can advantageously have significantly larger dimensions compared to the conductive pastes applied using the screen printing method or electrochemically metalized busbars, the shaded area on the solar cell is significantly reduced where conductor wires are electroplated on. The electroplating method according to the invention also allows a shorter exposure time compared to the conventional complete electroplating of the front contacts. A layer thickness of only about 5 μm is required for mechanically and electrically connecting conductors according to the invention such as collectors or busbars to the preferred seed layer. This amounts to about 20% of the layer thickness of well-known electroplating methods. The exposure time is correspondingly shorter.

Other advantages, characteristics and details are found in the following description in which at least one embodiment is described in detail by reference to the drawings. The described and/or depicted characteristics form the subject matter of the invention in themselves or in any useful combination, also independent of the claims, if applicable, and can in particular and in addition also be the subject matter of one or more separate invention(s). The same, similar and/or functionally equivalent parts are provided with the same reference characters.

For reasons of clarity, the following description is limited to embodiments where only the connection between the busbar conductor and the solar cell is formed by an electroplated cladding. This form of mechanically and electrically conductive connection can of course be transferred to connections between the solar cell and other conductors such as contact fingers and solar cell connective conductors and to the interconnection of conductors among themselves, such as between contact finger and busbar or busbar conductor, as well. Furthermore, the invention is described below for front-side (the side exposed to the sun) contact and conductor implementations by way of example. According to the invention, however, corresponding implementations on the backside are intended as well.

In the figures

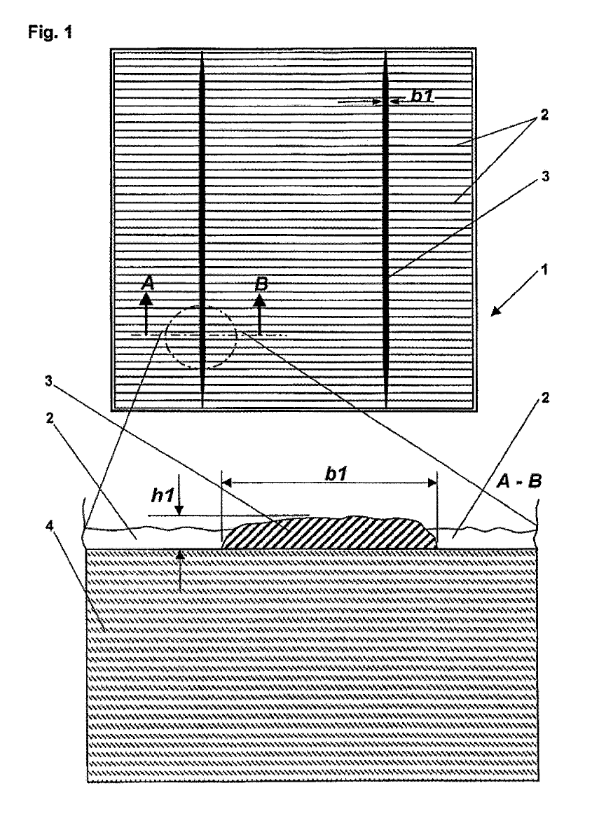

FIG. 1 in its upper part shows a customary cell made of a semi-conductor wafer which is depicted enlarged in the lower part of the figure as section A-B;

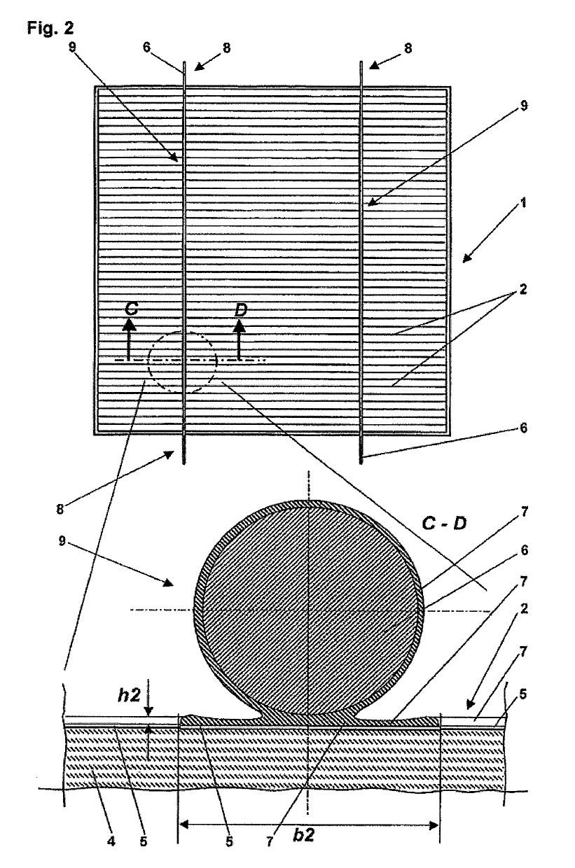

FIG. 2 in its upper part shows a solar cell according to the invention which is once again depicted enlarged in the lower part, with a round conductor as busbar which is mechanically and electrically conductively connected to the solar cell by a electroplated cladding;

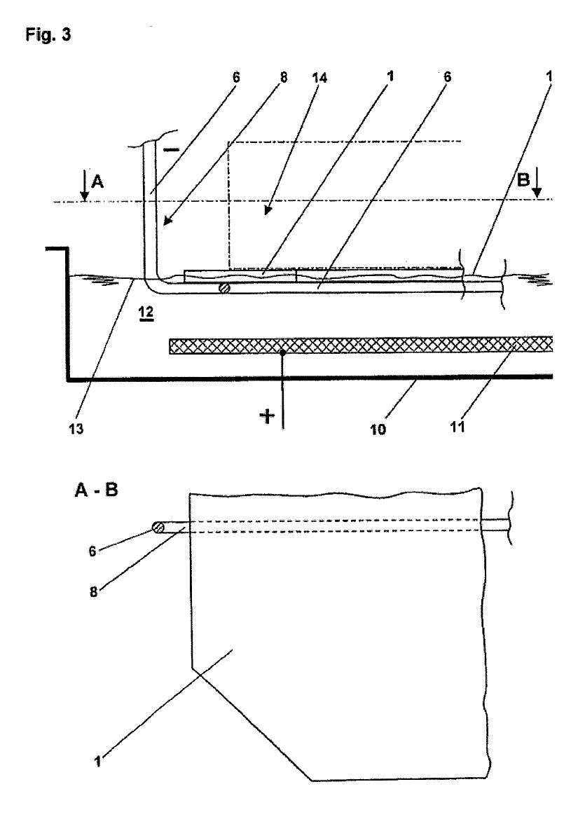

FIG. 3 shows an immersion bath system used to electroplate on busbar conductors;

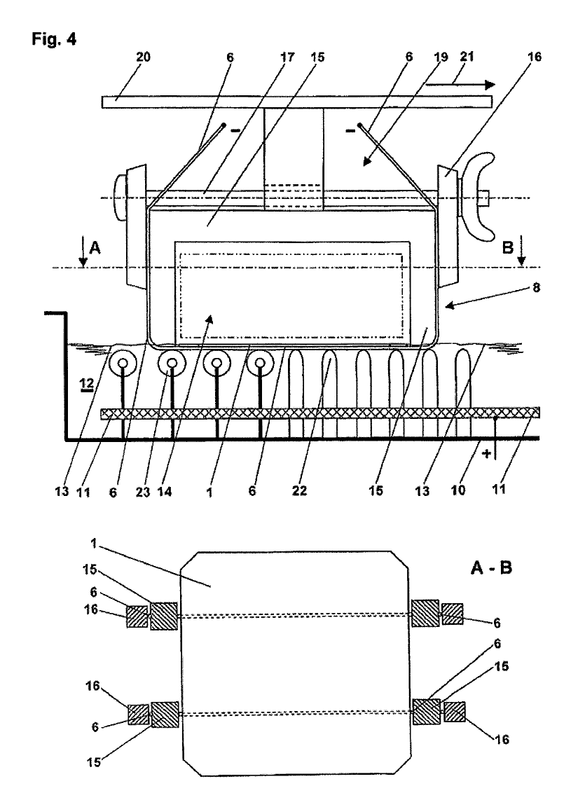

FIG. 4 shows two views of a solar cell with two busbar conductors in a continuous flow system;

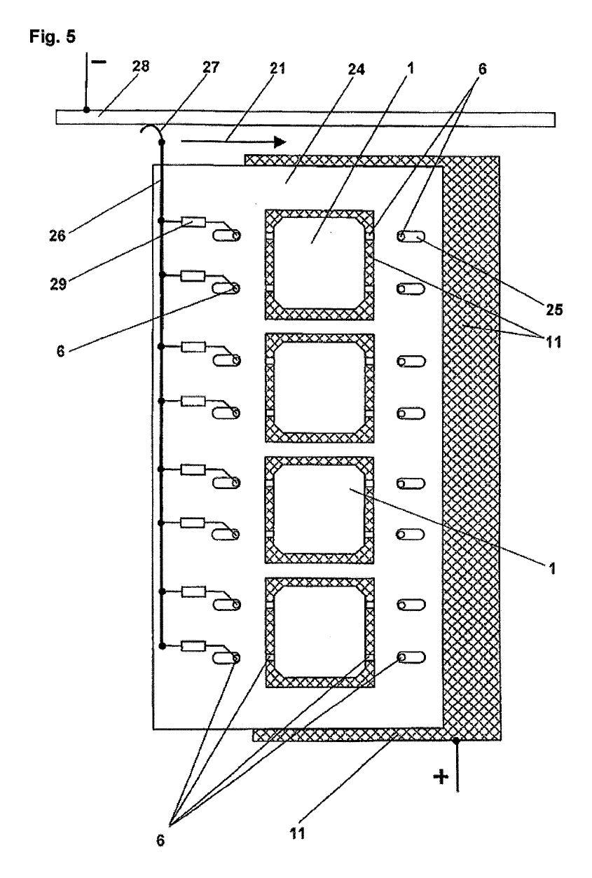

FIG. 5 shows a carrier with four solar cells which are conveyed through a continuous flow system;

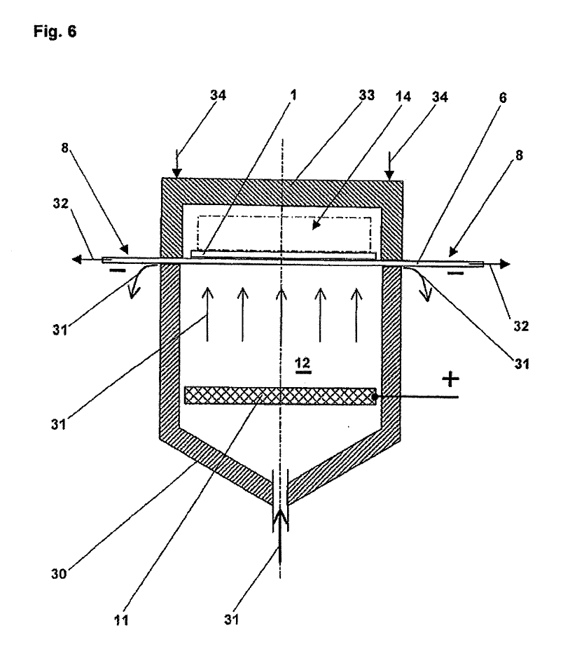

FIG. 6 shows a statically arranged cup plater used for the one-sided electroplating of substrates;

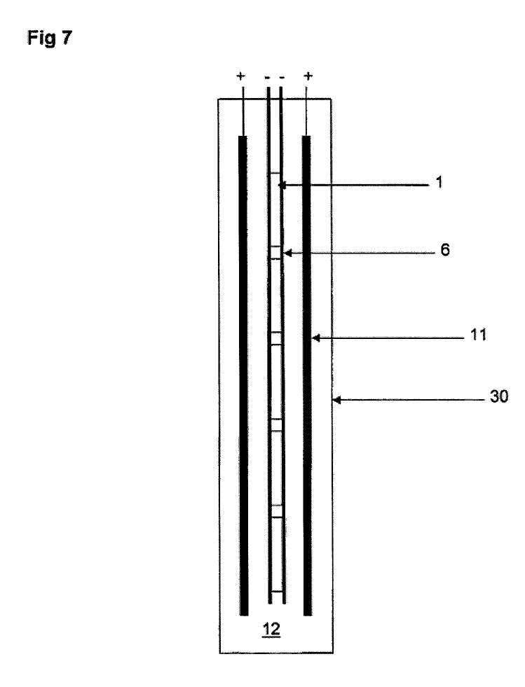

FIG. 7 shows a conventional vertically aligned electroplating system;

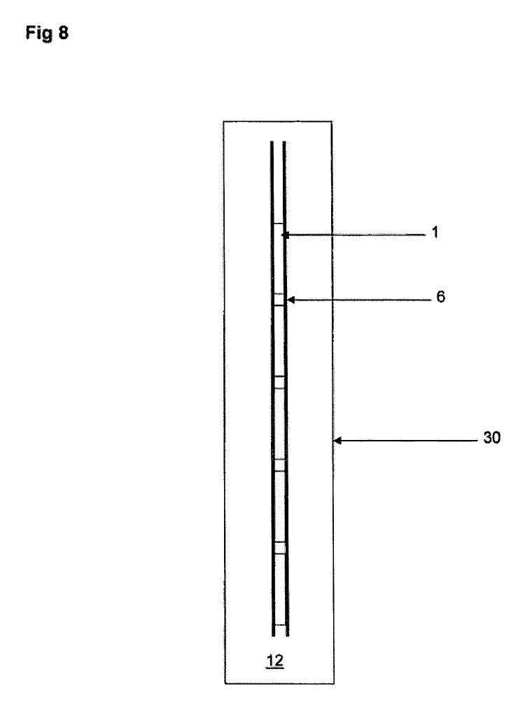

FIG. 8 shows a vertically aligned currentless deposition device for the production of solar cells according to the invention;

FIG. 9 shows a cross section of a solar cell arrangement according to the invention consisting of three solar cells with longitudinal and transverse conductors to connect neighboring solar cells to a circuit; and

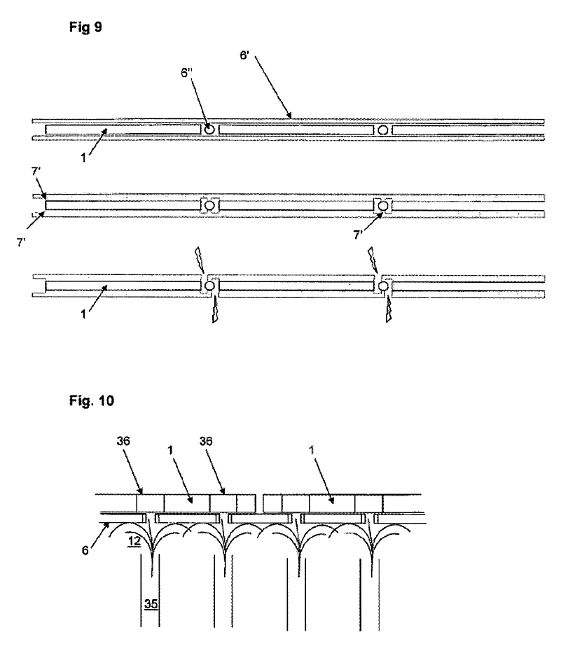

FIG. 10 shows two solar cells on a flexible circuit board with integrated conductors and apertures in the solar cells formed into electrical vias by electroplating.

In its upper part, FIG. 1 shows a conventional solar cell 1 with a view to the front (sun-exposed) side. The current-collecting contact fingers 2 of the grid structure run transversely across the entire solar cell 1. They consist of electrically conductive material, e.g. printed conductive silver paste or electrolytically deposited silver. Contact fingers 2 are electrically connected to the visibly wider busbars 3. These are usually manufactured at the same time and in the same way as contact fingers 2. Contact fingers 2 usually measure about 0.15 mm in width. Their height depends on the manufacturing process. In an industrial screen printing process, their height is about 5 to 25 μm. A height of up to 40 μm can be achieved in the hotmelt process. Electroplating the grid structure, a method that is not yet widespread, allows the height to be adjusted in these orders of magnitude as well. Furthermore, the specific conductivity of galvanically deposited layers is very high.

The lower part of FIG. 1 shows an enlargement in the area of busbar 3 in cross section A-B. The doped layers on the wafer 4 used to form solar cell 1 are not shown in this figure. Bus bar 3 usually has an uneven surface. Width b 1 is e.g. 2 mm. Height h 1 approximately corresponds to the height of contact fingers 2. Thus for example, if b 1=2 mm and h 1=0.03 mm, the cross-sectional area is about 0.06 mm². If each end of the two busbars conducts away half of the current generated and if the total current in the point of maximum output in the solar cell is 7 ampere, the current density at the ends of the busbars is about 30 A per mm². Because this current density is too high, especially in a heated solar cell, the ends are reinforced subsequently by means of the small flat strips commonly used for this purpose. Improved electric conductivity is achieved by means of galvanically produced busbars. This is another reason why efforts are made to manufacture contact fingers 2 in this way. However, the required electrical contacting in the electrolyte and the subsequent de-metalization of the contact agents make this manufacturing process more difficult, particularly since the back side of the solar cell usually must not come in contact with the electrolyte.

FIG. 2 shows an embodiment of a solar cell 1 according to the invention. A different size scale was chosen for the lower parts of FIGS. 1 and 2; this would need to be taken into account when comparing the two figures. Wafer 4 depicted in the section carries an electrically conductive seed layer 5 of the layout of the grid structure, i.e. contact finger 2 and of the areas intended for the busbars according to the invention, i.e. busbar conductors 9. This seed layer 5 consists e.g. of a thin, electrically conductive paste printing or of sprayed-on electrically conductive particles or conductive ink. Measure b 2 in turn indicates the width of seed layer 5 or of busbar seed layer (5) and the plating layer (7) or the conductive paste layer in the area of a busbar which is significantly smaller here than width b 1 at the current state of the art. Seed layer 5 must be cathodically biased for electroplating. Conductor 6 to be electroplated on, which e.g. consists of copper, can itself be very advantageously used as a power supply contact. It is completely or partially contacting seed layer 5 along the busbar section. The metal to be deposited, e.g. copper or silver, accumulates during the electroplating process from cathodic conductor 6 to seed layer 5 and in the presence of at least one initial contact point of conductor 6 on seed layer 5 from the latter to conductor 6 as well. An electrically highly conductive plating layer 7 is formed which connects conductor 6 to seed layer 5 and thus to wafer 4 or solar cell 1 very well, i.e. both mechanically firmly connected as well as electrically conductive. The same applies to embedding conductor 6 in a conductive paste layer with width b 2. It can be seen that the cross-sectional area of conductor 6 such as a busbar conductor 9 can be selected from a wide range of shapes and sizes. Nevertheless, when sunrays shine vertically on the solar cell, the shaded area is small compared to the current state of the art. It amounts to only ¼ if dimension b 2 and the diameter of a round conductor 6 of e.g. 0.5 mm is selected. Dimension b 2 of plating layer 7 can be selected to be even smaller. It is determined only by the attainable precision when positioning or placing seed layer 5 of wafer 4 on conductor 6 when the facility is loaded. If facility engineering measures are used to ensure that conductor 6 is in electric contact with all seed layers 5 of the many crossing and parallel contact fingers 2, or if the deposited metal electrolytically grows onto all contact fingers 2, the seed layer along the busbar or conductor 6 can be omitted completely. This once more reduces shading when oblique light shines on the solar cell, thereby achieving the minimum percent of shading. At a width of b 2=0.5 mm of seed layer 5 and thus of plating layer 7 below the two busbar conductors 9, shading is reduced by about 2% if an elongated conductor 6 is used compared to the total geometric surface area. This is an extraordinarily major improvement in the effectiveness of a solar cell. In FIG. 2, for example, conductor 6 is not in contact with seed layer 5 at the start of the electroplating process. The small gap is filled with metal during electroplating. This filling process is assisted by an effectively diffusing electrolyte. The preferred method, however, is to put conductor 6 in contact with seed layer 5 from the start in order to obtain an even larger cross-section for current transfer. The round cross-section of conductor 6 is advantageous. It can be handled and processed technically at low cost, e.g. can also be bent. Other cross-sectional shapes, e.g. oval or polygonal as well as non-wavy or wavy in its linear expansion are equally possible, however. Depending on the surface area of solar cell 1 and the material of conductor 6, its cross-sectional area can for example be in the range from 0.02 mm² to 10 mm² The preferred range is 0.1 mm² to 1 mm². In the area of conductor projection 8, conductor 6 can preferably be pressed flat in order to adapt it to the current practice of electrical interconnection to solar modules by means of thin tapes. Conductor projection 8 according to the invention takes over the function of the conductive strips which are required according to the state of the art. These conductors 6 or conductor projections 8 can very advantageously be used to supply the cathodic electroplating current during the electrolytic plating of the solar cells. Because the backside of the solar cell in one embodiment not shown in FIG. 2 should not be in contact with the electrolyte during electroplating, this electroplating process is carried out upside down, unlike shown in the lower part of this figure. Only the front side of the solar cell is situated in the electrolyte of the electrolytic cell, together with the e.g. elongated conductor 6. Conductor projections 8 are partially situated outside of the electrolyte, whereby they and the contact agents leading to them are not plated. Structured seed layer 5 of contact fingers 2 is also situated in the electrolyte. Compared to paste printing, electroplating creates contact fingers 2 that conduct electricity very well. Therefore, a lower height h 2 is sufficient for conducting away the generated and collected electricity. The number of busbar conductors 9 can also be increased or reduced as needed. To obtain a particularly high level of efficiency of solar cell 1 and the complete solar module, conductor 6 can be configured as a thin, electrically conductive tube. A fluid or gaseous coolant can be piped through this tubule to cool the electrical conductors, namely the busbars and their entire surroundings, in a sealed solar module, thus contributing to increasing the efficiency of the solar cells and the solar module without increasing shading.

FIG. 3 shows a processing container 10 with at least one anode 11 which is located in the electrolyte 12. This can be an immersion bath or a continuous flow system. Solar cell 1 is electroplated in this processing container 10. Its underside to be electroplated with structured seed layer 5 is located in electrolyte 12. The upper side in this embodiment, which is located above level 13, is free of electrolytes which could otherwise chemically attack and damage this side of the solar cell. It remains dry. Solar cell 1 is supported by at least one straight, preferably slightly tensioned conductor 6 and positioned in electrolyte 12 at a height such that the upper side remains dry. This requires that solar cell 1 be transported precisely through the equipment partially shown here, especially with respect to its height. If the back sides of the substrates 1, which are not to be electroplated, can be or should be moistened with electrolyte, these can also be arranged completely below the level 13 by placing the conductors 6 at the appropriate height. In this case, there is also the option of simultaneously electroplating the back sides of substrates 1 with anodes arranged on top.

In the example shown in FIG. 3, conductor 6 has a circular cross section. Other cross sections, e.g. oval or polygonal, are possible as well.

To ensure that solar cell 1 or its seed layer 5 is in contact with the entire length of conductor 6 if possible, the conductor must be stretched, i.e. at least slightly tensioned. The required pickups for conductors 6 are not depicted in FIG. 3. They pick up conductor 6 along a length that is longer than the longitudinal expanse of solar cell 1. At the same time, conductor 6 is redirected upwards by the pickups and brought out of electrolyte 12. Even a conductor that is mechanically stable in itself such as a punched part, etched part, cut part or the like can be supported by a pickup if pre-formed accordingly. The at least one free end of conductor projection 8 extends beyond the level 13 of electrolyte 12. There it can be electrically connected to the electroplating rectifier without being electroplated. Conductor 6 as a contact agent is electroplated according to the invention in electrolyte 12 and outside of electrolyte 12 is not plated. This very advantageously avoids de-metalization of the contact agents. Conductor 6 acts as a busbar conductor 9. Like conductor projections 8, it remains on finished solar cell 1. The pickups consist of electrical insulating material so that these surfaces are not metalized even if they pick up and divert the bare cathodic conductor 6 in the electrolyte. The pickups are transported through the continuous flow system on a carrier or conveyor. They are designed such that a clearance 14 is left on the top side of solar cell 1 which, as is shown below, can be used to support the electroplating process of solar cell 1.

The lower part of FIG. 2 shows the top view of one corner of solar cell 1. The straight, round conductor 6 supports solar cell 1; here, too, the pickups are not depicted. Conductor projection 8 is formed in the area of the pickups.

FIG. 4 shows an example of a device according to the invention in a continuous flow system where conductors 6 are arranged tensioned or non-tensioned on a pickup 15. The top part shows the side view while the bottom part shows the top view in section A-B. Pickups 15 in this case are U-shaped, thus forming the clearance 14 above solar cell 1. Clearance 14 allows, among other things, the conveyors 19 to be loaded with solar substrates 1 and emptied. In this embodiment, conductor 6 is bent over the legs of pickups 15 and redirected upwards. Outside of electrolyte 12, two clamps 16 are used to clamp and thereby fasten conductor 6 to pickup 15. Clamps 16 are manually pressed against pickups 15 by means of a clamping screw 17 with an associated wing nut in this example. In practice, however, conductors 6 will advantageously be handled and picked up automatically. This also guarantees that the processes will be reproducible. The negative terminal of the electroplating rectifier is connected to the free ends of conductors 6 or conductor projection 8. This will not result in the unwanted plating of the contact agents because they are located outside of electrolyte 12. Only a small portion of the cathodic wire overhang 8 is electroplated but this does not have any adverse effect on the method according to the invention. The positive terminal of the electroplating rectifier is electrically connected to the soluble or insoluble anode 11 which is located in the lower area of processing container 10. The invention also allows the use of unipolar and bipolar pulse rectifiers. Together with clamping devices 16, 17, among other things, pickups 15 form the conveyor 19 which transport solar cells 1 through the continuous flow system. A conveyor track 20 can be used for this purpose, for example, on which conveyor 19 is conveyed in the direction of transportation as indicated by the arrow 21. In the process, e.g. the height of conveyor 19 is adjusted such that the underside of the substrate or solar cell 1 is located below level 13 of electrolyte 12 and the upper side is located outside of electrolyte 12. When feeding the continuous flow system, solar cell 1 to be electroplated is placed on top of elongated conductor 6, preferably automatically. The height of the usually two conductors 6 is adjusted in relation to level 13 of electrolyte 12 such that a fluid meniscus is formed. This meniscus pulls solar cell 1 downwards in the direction of conductors 6. This force fastens solar cell 1 to the conductors at the beginning of the electroplating process. If e.g. seed layer 5 in the area of conductors 6 is uneven, or if solar cells 1 are slightly warped, it may be advantageous to continue exerting gentle forces at least at the start of the electroplating process such that conductors 6 and seed layers 5 of solar cell 1, which run parallel across conductors 6, are as completely as possible in contact. This also applies to conductors with a larger cross section which are only slightly tensioned and which have a wavy shape that allows them to compensate the differences in thermal expansion coefficients between the wafer material and the metallic conductors. Since the surfaces are in full contact with one another, metallic connection of these two electroplating partners occurs rapidly. To implement the optimal level of contact between conductors 6 and seed layers 5, solutions other than the utilization of the fluid meniscus described above can also be used in combination: When using a conductor 6 which is at least partially magnetic, at least one magnet can be placed on solar cell 1 across each conductor 6 in the dry clearance 14. The electromagnets or permanent magnets are transported through the continuous flow system with solar cell 1. They cause conductors 6 to form a gapless contact between conductors 6 and seed layer 5 of solar cell 1. At least in the starting area of the continuous flow system, stationary backing layers 22 or rotating backing layers 23 can be arranged in the continuous flow system below the tracks of conductors 6. These backing layers protrude through the anodes. They offer additional solutions: Backing layers 22, 23 are adjusted in height with respect to the material for electroplating and with respect to level 13 such that only the underside of solar cell 1, i.e. the side exposed to the sun, is moistened by electrolyte 12. Downpipes in the area of backing layers 22, 23 and near to conductors 6 allow electrolyte 12, which is conveyed in circular flow through the processing container 10, to flow out. The resulting suction pulls solar cell 1 very gently against the respective conductor 6 which is supported by backing layers 22, 23. Furthermore, weights can be placed in the clearance 14 on solar cell 1, instead of the magnets described above. These weights will push solar cells 1 in the direction of conductor 6 supported by the backing layers. In addition, there is the option of directing a fluid (a fluid or gaseous substance), preferably a stream of gas, against solar cells 1 in clearance 14. The stream or the ram pressure will strike the dry surface of solar cell 1 where in each case conductor 6, which is supported by backing layers 22, 23, runs on the underside in the continuous flow system or the immersion bath system. Finally, solar cell 1 to be electroplated can also be pressed against the respective supported conductor 6 by means of gentle spring forces emanating from pickup 15. As the cross section of the conductor according to the invention increases, line resistance is reduced. This has consequences for the thermal variation in stress that solar cells are exposed to both during the solar cell module manufacturing process as well as in practical operation. The difference in the thermal expansion coefficients of silicone and an electrically well-conducting metal, such as e.g. copper, is about 15*10⁻⁶/K. At a change in temperature of 100 K, the difference in linear expansion is about 0.2 mm. Such being the case, care should be taken to ensure that the seed layer for the busbar conductor has a very good adhesive strength on the wafer. To facilitate this, the firmness or the elasticity of the conductor material can be reduced e.g. by soft annealing or by the use of multistrand conductors such as braid wires. Not extending the conductor across the solar cell is very effective as well, e.g. meandering, triangular or sinusoidal pathways are suitable for absorbing thermal expansion differences. The amplitude of the respective waveform can range between e.g. 0.1 mm and 5 mm. The half-wavelength can be as long as the distance between two parallel contact fingers crossing the conductor. The distance can be greater as well. The resulting increase in length of the conductor and thus the increase in line resistance as well as shading are minor compared to an extended busbar conductor. The seed layer of the busbar conductor can be straight or as wavy as the conductor itself. Because conductors shaped in such a way can be tensioned only slightly, the measures described above to ensure that the conductor is in contact with the seed layer at the start of the electroplating process are particularly advantageous.

FIG. 5 shows a top view of a carrier 24 which transports four solar cells 1 e.g. through a horizontal continuous flow system. Carrier 24 consists at least on its surface of an electrically insulated material. Conductors 6 are deflected from the wet area into the dry area in apertures 25. The associated pickups for conductors 6 are not shown in this figure. The electrical connection of carrier 24 for the electroplating current is established e.g. through a conductor rail 26 and e.g. sliding contacts 27 that slide along the sliding path 28. Carrier 24 accommodates e.g. electric equipment on its dry upper surface. This can be electronic control units or measuring devices for quality control or alarm devices for break detection or, as shown, current distribution resistors 29. These equalize the resistance in the partial circuits of the here eight-fold electrical parallel circuits among themselves, which are always slightly different in practice. Here, too, it is very advantageous that neither the carriers 24 nor the contact agents have to be de-metalized after passing through the continuous flow system.

FIG. 6 shows a longitudinal section of a cup plater for electroplating wafers and solar cells 1 according to the invention. Cup 30 has a cross section which is adapted to the shape of the substrate or the solar cell 1. Electrolyte 12 flows into cup 30 from below. It flows through an anode 11 and reaches the underside of solar cell 1 to be electroplated. The flow arrows 31 show the direction of flow. Long conductors 6 are resting on the upper edge of the cup 30 as busbars. Where required, the tension force 32 acts in the direction of the arrows shown. The upper portion 33 of cup 30 can rest on conductors 6. Electrolyte 12 flows out of cup 30 on all sides through the gap formed in the process. If force is applied in the direction of force arrows 34, conductors 6 can be jammed by upper portion 33. Clearance 14 in turn accommodates the means for bringing solar cell 1 and conductors 6 close together, as described by the example of FIG. 4. Here, too, backing layers, which are not shown in FIG. 6, can be arranged at the underside in the area of conductors 6 in cup 30. Since the electrical connection of the electroplating rectifier (not shown) occurs outside of electrolyte 12 or outside of the electrolytic cell, the contact agents do not need to be de-metalized. Conductor projection 8 can be re-used later for electrical wiring of individual solar cells 1 into solar modules. This allows some steps of the method that are required given the present state of the art to be saved. Since the surface to be electroplated is in direct electrical contact, illuminating the side exposed to the sun is not required here as well. In semiconductor wafers, the conductors or busbar conductors are located in the area of use, i.e. the few circuits located below it can no longer be used later on. Especially in large-diameter wafers, however, excellent layer-thickness distribution is achieved because the electroplating current is fed in over a large surface area.

FIG. 7 shows a conventional, vertically aligned electroplating system with a container (30) filled with electrolyte (12), five solar cells (1) stacked vertically on top of each other lengthwise which are connected to each other when the solar cell connective conductors (6) are electroplated. This vertical electroplating system is also suitable for the production of electroplated solar cells according to the invention but, compared to the cup plater described in FIG. 6, allows higher current densities to be implemented, thus resulting in faster deposition rates.

FIG. 8 shows a vertically aligned currentless deposition system for the production of solar cells according to the invention where the mechanically and electrically conductive cladding is produced electrochemically, i.e. by redox deposition on the solar cell and conductors. In the present case, five solar cells (1) are vertically arranged on top of each other lengthwise in the container (30) in solution with the dissolved redox components (12) which are connected with each other through solar cell connective conductors (6) during the currentless electrolytic deposition of the cladding from solution (12).

FIG. 9 schematically illustrates a solar cell arrangement according to the invention consisting of three solar cells (1) in cross section where longitudinal conductors 6′ are arranged above and below cells (1) and transverse conductors 6″ are arranged in the space between adjacent cells. During the production process, these conductors (6′, 6″) are mechanically and electrically conductively connected by means of the resulting electroplated cladding (7′). In the next production step, these conductors (6′, 6″) are then partially separated such that they result in the desired circuit, in this case, a series circuit of cells. The same method allows solar cell strings or complete solar cell matrices to be produced easily and cost-efficiently.

FIG. 10 schematically illustrates two solar cells (1) lying on top of a flexible circuit board (6) with integrated conduits. Solar cells (1) have vias (35) to conduct the current from the side exposed to the sun (top) to the back side (bottom). To produce vias (35), openings (holes) are rendered electrically conductive by supplying electrolytes (36)—in the present case, via spray nozzles (12) arranged underneath (alternatively, electrolytes can be supplied by means of an electrolyte bath as well)—and are electroplated on (closed) or electroplated on the inside (internally coated). Thus, electroplating takes place in a controlled manner on only the areas coated with electrolytes.

List of reference numbers

| | |
|---|---|
| 1 | Solar cell |
| 2 | Contact finger, grid structure |
| 3 | Conductor on cell |
| 4 | Wafer |
| 5 | Seed layer |
| 6 | Conductor |
| 7 | Conductive cladding* |
| 8 | Conductor projection |
| 9 | Busbar conductor |
| 10 | Processing container |
| 11 | Anode |
| 12 | Electrolyte |
| 13 | Level |
| 14 | Clearance |
| 15 | Pickup |
| 16 | Clamp |
| 17 | Clamping screw |
| 19 | Conveyor |
| 20 | Conveyor track |
| 21 | Direction of conveyance arrow |
| 22 | Backing layer, stationary |
| 23 | Backing layer, rotating |
| 24 | Carrier |
| 25 | Aperture |
| 26 | Conductor rail |
| 27 | Sliding contact; brush, roller |
| 28 | Sliding path |
| 29 | Current distribution resistor |
| 30 | Cup, cuvette, container |
| 31 | Direction of flow arrow |
| 32 | Tension force |
| 33 | Upper portion |
| 34 | Direction of force arrow |
| 35 | Via |
| 36 | Electrolyte feed |

*preferably manufactured electrochemically, galvanically or by plasma spraying

1. Solar cell (1) where at least one conductor (6) is mechanically and electrically conductively connected to the solar cell (1) and/or other conductors by means of conductive cladding (7).

2. Solar cell according to claim 1 where the conductor is preferably selected from the group consisting of contact fingers (2), collectors, preferably busbars, more preferably busbar conductors (9) and solar cell connective conductors.

3. Solar cell with contacts located on the front and/or back side for conducting away the current generated by means of many contact fingers (2) and with at least one busbar, where at least the one busbar is implemented as a busbar conductor (9) whose conductor (6) is mechanically and electrically conductively connected to the contact fingers (2).

4. Solar cell according to claim 3 with front contacts on the side exposed to the sun for conducting away the current generated by means of many contact fingers (2) on the side exposed to the sun and at least one busbar on the side exposed to the sun, where the at least one busbar is implemented as a busbar conductor (9) whose conductor (6) is mechanically and electrically conductively connected to the contact fingers (2).

5. Solar cell according to one of claim 3 or 4 where the at least one busbar conductor is mechanically and electrically conductively connected to the solar cell and/or other conductors by means of electroplated cladding.

6. Solar cell according to one of claims 3 to 5 where at least one busbar seed layer (5) which is electrically conductively connected to a contact finger seed layer (5) has a mechanically solid and electrically conductive connection to at least one busbar conductor (9), where this connection between the busbar seed layer (5) and the busbar (9) was preferably established by (i) electroplating or (ii) embedding and baking into a conductive paste.

7. Solar cell according to one of claims 1, 2 and 6 where the conductive cladding (7) is selected from claddings produced electrolytically, galvanically or by plasma spraying.

8. Solar cell according to one of claims 1, 2, 6 and 7 where the conductive cladding is selected from conductive metals or metal alloys, preferably metals and metal alloys based on copper, silver, nickel and/or tin, and/or aluminum, conductive hydrocarbons and/or carbons.

9. Solar cell according to one of claims 1, 2 and 6 to 8 where the conductive cladding (7) consists of one or more layers of cladding, preferably made of different conductive materials.

10. Solar cell according to one of claims 1 to 9 where at least one conductor (6), preferably a collector, more preferably a busbar conductor (9), preferably protrudes at least on one side of the solar cell (1) beyond the surface area of said solar cell as a conductor projection (8) for the electrical connection of the solar cell (1).

11. Solar cell according to one of claims 1 to 10 where, by means of an electrical contact of the conductor, preferably a collector or busbar conductor (6), to many contact fingers (2), said conductor is electroplated without a seed layer (5) onto the contact fingers (2) only or is embedded in the conductive paste.

12. Solar cell according to one of claims 1 to 11 comprising a seed layer (5) where the seed layer (5) consists of an electrically conductive paste print or of sprayed on, electrically conductive particles, or conductive ink, or a conductive or nucleating area on the solar cell.

13. Solar cell according to one of claims 1 to 12 where the shape of the conductor (6) is elongated, meandering, triangular or sinusoidal and where the shape is formed by a wire, a punched part, an etched part or a cut part.

14. Solar cell according to one of claims 1 to 13, preferably consisting of semiconductor material, more preferably on silicone basis, where the thermal expansion coefficient of the conductor, preferably a collector or a busbar conductor (6), is adapted to the thermal expansion coefficient of the solar cell wafer by alloying.

15. Method for connecting solar cells (1) to at least one conductor and/or connecting conductors on solar cells (1) with each other where at least one electrically conductive conductor is mechanically and electrically connected on the solar cell (1) and/or on at least one other conductor by means of the deposition of a conductive cladding (7) preferably (see claim 16) from solution.

16. Method according to claim 15 where the conductive cladding (7) is selected from cladding that was produced electrolytically, galvanically or by plasma spraying.

17. Method according to one of claims 15 and 16 where the conductive cladding is selected from conductive metals or metal alloys, preferably metals and metal alloys based on copper, silver, nickel and/or tin, conductive hydrocarbons and/or carbons.

18. Method according to one of claims 15 to 17 where the conductive cladding (7) consists of one or several layers of cladding, preferably made of different conductive materials.

19. Method according to one of claims 15 to 18 where the conductor is selected from the group consisting of contact fingers (2), collectors, busbar conductors (9) and solar cell connective conductors.

20. Method, preferably according to one of claims 15 to 19, for electroplating solar cells (1) in electrolytic cells where at least one electrically conductive conductor, preferably a collector or a busbar conductor (6), lies flat against the surface of the solar cell (1) to be electroplated to create at least a partial electrical contact to supply the electroplating current such that this conductor (6) is permanently mechanically and electrically connected to the solar cell (1) by electroplating.

21. Method according to one of claims 15 to 20, preferably 20, where the at least one conductor, preferably a collector or a busbar conductor (6) support(s) the solar cell (1) in the electrolytic cell during the electroplating process by means of pickups (15) or carriers (24) that extend beyond the length of the solar cell (1) and preferably position its height level and preferably transport it such that only the underside of the solar cell (1) to be electroplated is located in the electrolyte.

22. Method according to one of claims 15 to 21, preferably 20 or 21, where at least the one conductor (6), preferably a collector or a busbar conductor (6), is pressed or drawn against the solar cell (1), preferably against the seed layer (5) to be electroplated of the solar cell (1) by means of backing layer(s) (22, 23) on the one side of the solar cell (1) and by a force, preferably weight force, applied pressure, ram pressure exerted by a fluid, or by means of spring force or magnets on the other side of the solar cells (1), or by fluid suction.

23. Method according to one of claims 15 to 22, preferably 20 to 22, where the electroplating current is supplied into the conductor (6), preferably a collector or busbar conductor (6), through at least one conductor projection (8) outside of the electrolyte which extends beyond the level (13) of the electrolyte (12).

24. Method according to one of claims 15 to 23, preferably 20 to 23, where the conductors, preferably collectors or busbar conductors (6) which were preferably electroplated onto the solar cell (1) in continuous flow systems, immersion bath systems or cup platers, remain on the solar cell (1) and are subsequently utilized for further processing the finished solar cell.

25. Method according to one of claims 15 to 24 for manufacturing a solar cell according to claims 1 to 14.

26. Device for depositing a mechanically connecting and electrically conductive cladding (7) from solution onto solar cells (1) in electrolytic cells, comprising means (15, 16, 30, 32, 33) for receiving at least one conductor, preferably a collector or a busbar conductor (6), which lies at least partially flat against the surface layer to be deposited in the electrolyte (12) of the electrolytic cell, preferably a seed layer (5) of the solar cell (1) preferably providing electrical contact and which preferably simultaneously supports the solar cell (1).

27. Device for electroplating solar cells (1) in electrolytic cells, preferably according to claim 26, comprising means (15, 16, 30, 32, 33) for accommodating at least one conductor, preferably a collector or a busbar conductor (6) at least partially contacting the surface to be electroplated, preferably providing electrical contact with the solar cell (1), preferably a seed layer (5) in the electrolyte (12) of the electrolytic cell and preferably supporting the solar cell (1), wherein the conductor projections (8) for connecting the electroplating rectifier preferably protrude beyond the level (13) of the electrolyte (12).

28. Device according to claim 26 or 27 comprising a pickup (15) as a means for exerting a tensioning force to at least one area of the conductor which is located in the electrolyte (12) of the electrolytic cell.

29. Device according to one of claims 26 to 28 comprising means that exert a pulling or pressing force between the conductor (6) and the solar cell (1) with or without backing layers (22, 23), preferably as weight force, ram pressure, magnetic force, spring force or suction.

30. Device according to one of claims 26 to 29, comprising means (6, 15, 24) to position the solar cell (1) in a processing container (10, 30) such that the level (13) of the electrolyte (12) reaches up to the underside of the solar cell (1) only.

31. Device according to one of claims 26 to 30 for implementing a method according to claims 15 to 25.
